(19) United States
(12) Patent Application Publication
(10) Pub. No.: US 2026/0215008 A1
(43) Pub. Date: Jul. 23, 2026

(54) HIGH DYNAMIC RANGE PIXEL

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 19/454,942

(22) Filed: Jan. 21, 2026

(30) Foreign Application Priority Data
Jan. 23, 2025 (FR) FR2500682

(51) Int. Cl. H10F 39/15; H10F 39/00

(52) U.S. Cl. CPC H10F 39/151; H10F 39/8027

(57) ABSTRACT

A high dynamic range pixel is formed in a portion of a semiconductor substrate that extends vertically across an entire thickness of the substrate between first and second surfaces, and is laterally delimited by a vertical insulating structure. A first pinned photodiode and a second pinned photodiode are arranged in this portion. The first pinned photodiode extends vertically across only part of the thickness of the substrate, on the side of the first surface. The second pinned photodiode extends vertically in the substrate between the first and second surfaces and comprises a first portion arranged between the first pinned photodiode and the second surface and a second portion arranged between the first pinned photodiode and the vertical insulating structure.

### PRIORITY CLAIM

This application claims the priority benefit of French Application for Patent No. FR2500682, filed on January 23, 2025, the content of which is hereby incorporated by reference in its entirety to the maximum extent allowable by law.

### TECHNICAL FIELD

The present disclosure generally concerns pixels and light or image sensors comprising such pixels and, more particularly, high dynamic range (HDR) pixels.

### BACKGROUND

A pixel is an element configured to convert light received in an operating wavelength range of the pixel into an output signal of the pixel, for example a current or a voltage, having a value representative of a quantity of light received.

When a sensitive pixel operates in low light conditions, a small variation in the amount of light received results in a corresponding variation in the output signal of the pixel. However, a disadvantage of a sensitive pixel is that, when it operates in bright conditions, the output signal of the pixel saturates, and its value is no longer representative of the quantity of light received.

Conversely, a less sensitive pixel enables, when it operates in bright conditions, its output signal not to saturate and to be well representative of the quantity of light received. However, when a less sensitive pixel operates in low light conditions, the quantity of light received is not sufficient to cause a corresponding variation in the output signal of the pixel, and the light received is not detected by the pixel.

To overcome the above disadvantages, there have been provided so-called high dynamic range pixels, that is, pixels enabling to obtain a pixel output signal which varies with the quantity of light received, whether the pixel is operating in low light or bright conditions. As an example, a pixel is said to have a high dynamic range when its output signal varies over a dynamic range of at least 80 dB, preferably at least 90 dB. More preferably, a pixel is said to have a high dynamic range when its output signal varies over a dynamic range of at least 100 dB, preferably at least 115 dB.

A known type of pixel comprises a pinned photodiode enabling to convert the light received by the pixel during a light integration phase into photogenerated charges and to store these photogenerated charges prior to a pixel readout phase, the pinned photodiode then behaving as a capacitive element for storing the photogenerated charges. During the readout phase, the photogenerated charges stored in the photodiode are read out and converted into the pixel output signal. The dynamic range of such a pixel depends on the surface area of the photodiode which receives light, on the duration of the integration phase, on the quantum efficiency (QE) of the photodiode, on the light transmission properties of one or more of filters of the pixel, and on the capacitance value of the pinned photodiode.

To implement HDR pixels, there have been provided pixels comprising, in a portion of a semiconductor substrate, two pinned photodiodes insulated from each other and each extending across the entire thickness of the substrate, from one to the other of the two main surfaces of the substrate. A first one of the two photodiodes has, in planes parallel to the main surfaces of the substrate, dimensions smaller than those of the second photodiode. Instead of, or in addition to, varying the dimensions of the two photodiodes, a filter attenuating the light identically received over the entire operating range of the pixel can be arranged above the first photodiode. By separately reading from the two photodiodes after a light integration phase common to both photodiodes, an output signal of the pixel is reconstructed from the quantity of photogenerated charges read from each of the two photodiodes. However, such an HDR pixel requires two photodiodes arranged side by side, which increases the surface area of the pixel with respect to the case of a pixel comprising a single photodiode. Further, the reconstruction of the pixel output signal based on the reading from each of the two photodiodes may be complex to implement.

To implement an HDR pixel, it has also been proposed, in a pixel comprising a single pinned photodiode, to reconstruct an output signal of the pixel from a plurality of output signals of the pixel corresponding to different integration (or exposure) times. However, this makes the reconstruction of the output signal of the pixel and thus of an image from the output signals of a plurality of pixels more complex, due to the fact that, for example, the reconstructed image comprises potential artifacts such as motion blur or effects of flickering of light sources between two successive images.

More generally, known HDR pixels have disadvantages, at least some of which it is desirable to overcome.

There exists a need for an HDR pixel overcoming all or part of the disadvantages of known HDR pixels.

There is a need in the art to overcome all or part of the disadvantages of known HDR pixels.

### SUMMARY

An embodiment provides a high dynamic range pixel comprising: a portion of a semiconductor substrate extending vertically across an entire thickness of the substrate from a first surface to a second surface of the substrate, and being laterally delimited by a vertical insulating structure; and a first pinned photodiode and a second pinned photodiode arranged in said portion, wherein: the first pinned photodiode extends vertically across only part of the thickness of the substrate, on the side of the first surface; and the second pinned photodiode extends vertically across the substrate between the first and second surfaces and comprises a first portion arranged between the first pinned photodiode and the second surface and a second portion arranged between the first pinned photodiode and the vertical insulating structure.

According to an embodiment, the pixel is configured to receive light on the side of the second surface.

According to an embodiment, the second portion of the second pinned photodiode is arranged between the first pinned photodiode and the vertical insulating structure in planes parallel to the first and second surfaces.

According to an embodiment, the first and second pinned photodiodes are insulated from each other.

According to an embodiment, the substrate is doped with a first conductivity type, and a doped region of a second conductivity type is arranged between the first pinned photodiode and the first portion of the second pinned photodiode so as to insulate the first and second pinned photodiodes from each other.

According to an embodiment, the pixel comprises at least one sense node arranged in the portion of the substrate on the side of the first surface, and at least one vertical transfer gate penetrating into the portion of the substrate from the first surface and being configured to control charge transfers from the first pinned photodiode to said at least one sense node and from the second pinned photodiode to said at least one sense node.

According to an embodiment, the at least one sense node comprises a single sense node.

According to an embodiment, the at least one sense node comprises a first sense node and a second sense node; said at least one transfer gate comprises a first transfer gate configured to control charge transfers from the first pinned photodiode to the first sense node, and a second transfer gate configured to control charge transfers from the second pinned photodiode to the second sense node.

According to an embodiment, the first and second pinned photodiodes are configured so that a photogenerated charge storage capacitance of the first pinned photodiode is greater than that of the second pinned photodiode.

Another embodiment provides a light sensor comprising at least one pixel such as defined hereabove, the sensor comprising a circuit for controlling said at least one transfer gate, the circuit being configured, during a phase of reading from said at least one pixel, to simultaneously control a charge transfer from the first pinned photodiode to the single sense node and a transfer of photogenerated charges from the second pinned photodiode to the single sense node.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a simplified cross-section of a high dynamic range (HDR) pixel;

FIG. 2 shows another simplified cross-section view of the HDR pixel of FIG. 1;

FIG. 3 shows another simplified cross-section view of the HDR pixel of FIG. 1;

FIG. 4 shows another simplified cross-section view of the HDR pixel of FIG. 1;

FIG. 5 shows a simplified cross-section of an HDR pixel;

FIG. 6 shows another simplified cross-section view of the HDR pixel of FIG. 5;

FIG. 7 shows another simplified cross-section view of the HDR pixel of FIG. 5;

FIG. 8 shows another simplified cross-section view of the HDR pixel of FIG. 5;

FIG. 9 another simplified cross-section of an HDR pixel;

FIG. 10 shows another simplified cross-section view of the HDR pixel of FIG. 9;

FIG. 11 shows still another simplified cross-section view of the HDR pixel of FIG. 9;

FIG. 12 shows another simplified cross-section view of the HDR pixel of FIG. 9;

FIG. 13 shows in a curve an example of the dynamic range of an HDR pixel; and

FIG. 14 shows in a curve an example of the dynamic range of an HDR pixel.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail. In particular, the various known electronic systems and applications in which one or more HDR pixels may be provided have not been detailed, the embodiments and variants of IDR pixels described herein being compatible with these known electronic systems and applications.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or ₅°.

In the following description, when reference is made to a pinned photodiode, this means that the photodiode and/or the pixel which comprises it are configured so that, at the beginning of a phase of light integration by the pixel, the photodiode is fully depleted. To achieve this, as an example, either a heavily-doped layer with a doping type opposite to that of the photosensitive portion is provided, or an electrostatic potential is applied to capacitive elements, for example of metal-oxide-semiconductor type.

There is here provided a high dynamic range (HDR) pixel comprising a first pinned photodiode and a second pinned photodiode arranged in a semiconductor substrate. The semiconductor substrate extends across the thickness from a first main surface of the substrate to a second main surface of the substrate. The two pinned photodiodes, and, more generally, the pixel which comprises them, are configured so that the two pinned photodiodes are insulated from each other, or, in other words, so that charges photogenerated in any of the two pinned photodiodes cannot reach the other of the two photodiodes. The second pinned photodiode extends vertically across the entire thickness of the substrate and is laterally delimited by a vertical insulating structure, and the first pinned photodiode is arranged in the second pinned photodiode, on the side of the first main surface of the substrate.

A portion of the second pinned photodiode is arranged between the first pinned photodiode and the insulating structure, for example in planes parallel to the main surfaces of the substrate.

This enables to read from the second pinned photodiode with elements arranged on the side of the first main surface of the substrate.

As an example, this further implies that the first pinned photodiode has lateral dimensions, for example measured in planes parallel to the first and second surfaces of the substrate, smaller than those of the second pinned photodiode, whereby, for example, the value of the capacitance of the first pinned photodiode may be higher than that of the capacitance of the second pinned photodiode, for example due to a better electrostatic control in the first pinned photodiode, enabling to more strongly dope it than the second pinned photodiode despite its smaller volume. More generally, both pinned photodiodes are preferably configured so that the capacitance of the first pinned photodiode is greater than that of the second pinned photodiode, which enables the first pinned photodiode to be less sensitive than the second pinned photodiode to a same received quantity of light.

Another portion of the second pinned photodiode is arranged between the first pinned photodiode and the second main surface of the substrate. In other words, the first pinned photodiode extends vertically across only part of the thickness of the substrate, from the first surface of the substrate. Thus, when the pixel receives light on the side of its second surface, the received light is partly absorbed by this portion of the second pinned photodiode before reaching the first pinned photodiode.

This arrangement of the two pinned photodiodes enables the first pinned photodiode to be less sensitive than the second pinned photodiode to the light received by the pixel on the side of the first surface.

Further, this arrangement of the two pinned photodiodes enables not to increase the pixel surface area as compared with a pixel which would comprise a single photodiode corresponding to the second pinned photodiode.

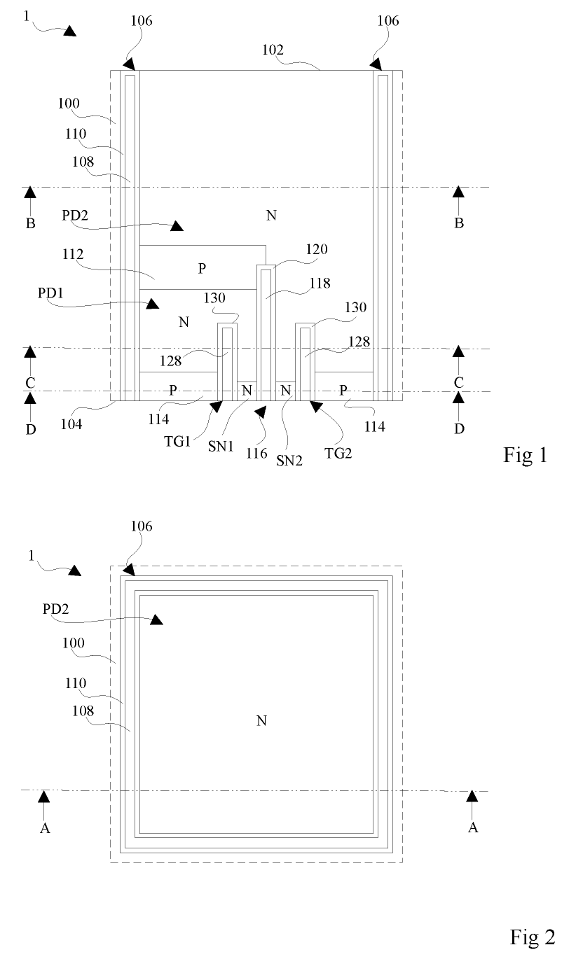

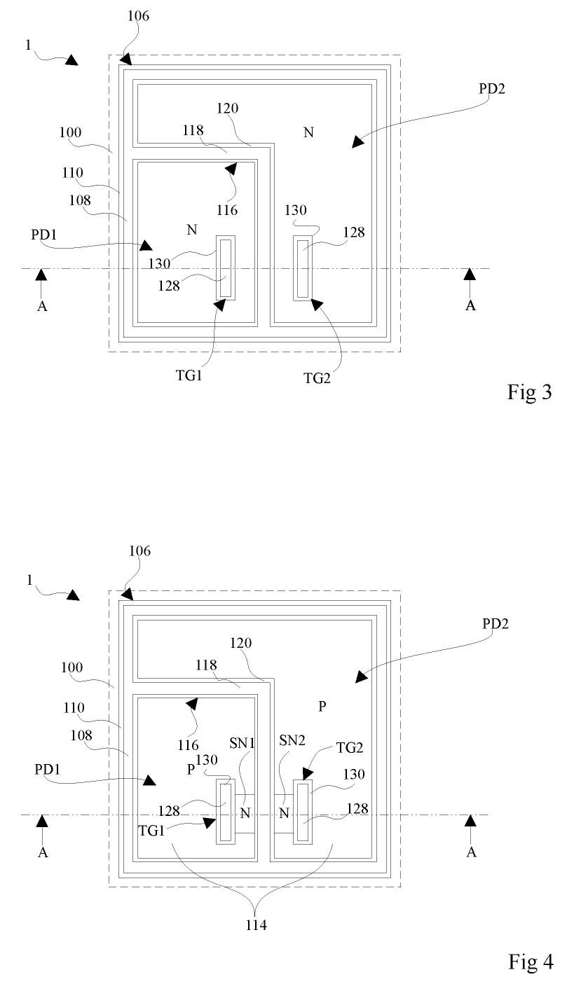

FIGS. 1 to 4 are simplified cross-section views illustrating an embodiment of such an HDR pixel 1. More particularly, FIG. 1 is a cross-section view taken in a cross-section plane AA, FIG. 2 is a cross-section view taken in a plane BB orthogonal to plane AA, FIG. 3 is a cross-section view taken in a plane CC orthogonal to plane AA, and FIG. 4 is a cross-section view taken in a plane DD orthogonal to plane AA.

Pixel 1 comprises a portion of a semiconductor substrate 100, for example made of silicon. Substrate 100 extends across the thickness from a main surface 102 of the substrate to a main surface 104 of the substrate (FIG. 1). As an example, the substrate is doped with a first conductivity type, for example type N.

This portion of substrate 100 belonging to pixel 1 is laterally delimited, that is, in planes parallel to surfaces 102 and 104, by a vertical insulating structure 106. Preferably, the portion of substrate 100 belonging to pixel 1 is entirely laterally delimited by structure 106. Preferably, structure 106 runs through substrate 100 across its entire thickness. As an example, this portion of substrate has, in planes parallel to surfaces 102 and 104, a square or rectangular shape (FIGS. 2, 3, and 4), although other shapes can be envisaged.

Preferably, structure 106 is a capacitive deep trench isolation (CDTI), that is, a trench filled with an electrically-conductive core 108 covered by an insulating sheath 110. As an alternative example, structure 106 is a deep trench isolation (DTI), that is, a trench filled with an insulator, the deep trench isolation preferably being bordered by a passivation layer, for example by a heavily-doped layer of a conductivity type opposite to that of the substrate.

Pixel 1 comprises two pinned photodiodes PD1 and PD2 arranged in this portion of substrate 100. As an example, each of photodiodes PD1 and PD2 thus comprises one part of this portion of substrate 100, which is doped with the same type as substrate 100, that is, type N in the example of FIGS. 1 to 4.

Photodiode PD1 extends vertically across only part of the thickness of substrate 100, on the side of surface 104. For example, in other words, photodiode PD1 extends vertically from surface 104 across only part of the thickness of substrate 100, and thus does not reach surface 102.

Photodiode PD2 extends vertically in substrate 100 between the two surfaces 102 and 104.

Photodiode PD2 comprises, for example in a direction orthogonal to surfaces 102 and 104, a portion (at the top left in the cross-section view of FIG. 1) arranged between photodiode PD2 and surface 102. In other words, this portion of photodiode PD2 separates photodiode PD1 from surface 102. Photodiode PD2 has, for example, lateral dimensions, for example measured in planes parallel to surfaces 102 and 104, which are the same as that of the portion of substrate 100, at least between photodiode PD1 and surface 102.

Photodiode PD2 further comprises, for example in planes parallel to surfaces 102 and 104, a portion arranged between photodiode PD1 and structure 106. In other words, this portion of photodiode PD2 separates photodiode PD1 from structure 106, and, more exactly, from at least a portion of insulating structure 106 (the portion on the right-hand side in FIG. 1). This portion of photodiode PD2 extends vertically from the surface 104 of the substrate.

In other words, photodiodes PD1 and PD2 are arranged relative to one another so that photodiode PD2 comprises a portion which extends vertically across the entire thickness of substrate 100, for example from surface 102 to surface 104, and a portion which extends between photodiode PD1 and surface 102, for example all the way to surface 102.

In other words, the portion of substrate 100 in which are arranged photodiodes PD1 and PD2 is formed of a first volume and of a second volume, complementary to each other, the first volume extends from surface 104 across only part of the thickness of substrate 100 and has lateral dimensions smaller than those of this substrate portion. Photodiode PD1 is arranged in the first volume, for example occupying all or part of the first volume. Photodiode PD2 is arranged in the second volume, for example occupying all or part of the second volume. Further, photodiode PD2 comprises a portion extending from surface 102 to surface 104.

As an example, a doped well 114 of a conductivity type opposite to that of substrate 100, that is, a P-type doped well 114 in the example of FIGS. 1 to 4, is arranged on the side of surface 104. This well 114 extends vertically in substrate 100 from its surface 104, across only part of the thickness of photodiode PD1. Well 114 is laterally delimited by structure 106. As an example, each of photodiodes PD1 and PD2 comprises a portion of this well.

As an example, although this is not illustrated in FIGS. 1 to 4, a doped layer of the conductivity type opposite to that of substrate 100 may be formed on the side of surface 102, this doped layer having, for example, a surface coplanar with surface 102, and extending, for example, over the entire surface 102 of substrate 100. As an example, photodiode PD2 comprises the portion of this doped layer which is laterally delimited by structure 106.

The two photodiodes PD1 and PD2 are insulated from each other.

More particularly, in a direction orthogonal to surfaces 102 and 104 (vertically in FIG. 1), photodiodes PD1 and PD2 are insulated from each other by a doped well 112 of a conductivity type opposite to that of substrate 100, that is, a P-type doped well 112 in the example of FIGS. 1 to 4. In practice, well 112 can be considered as forming part of each of the two photodiodes PD1 and PD2. It should be noted that well 112 does not separate photodiode PD2 into two portions in a direction orthogonal to surfaces 102 and 104.

Further, in planes parallel to surfaces 102 and 104, the two photodiodes PD1 and PD2 are insulated from each other by a vertical insulating structure 116. Structure 116 penetrates vertically into substrate 100 from surface 104, across only part of the thickness of substrate 100. Structure 116 penetrates vertically into substrate 100 across at least the entire thickness of photodiode PD1, for example across substantially the same thickness as photodiode PD1.

In the embodiment of FIGS. 1 to 4, structure 116 is a deep capacitive isolation trench filled with a conductive core 118 coated with an insulating sheath 120.

In the example of FIGS. 1 to 4, the core 108 of structure 106 and the core 118 of structure 116 form a continuous element, and the sheath 110 of structure 106 and the sheath 120 of structure 116 also form a continuous element, for example because sheaths 110 and 120 have been formed during a same deposition step and cores 108 and 118 have also been formed during a same deposition step. However, in other, non-illustrated examples, cores 108 and 118 are insulated from each other by one and/or other of sheaths 110 and 120.

Further, in other non-illustrated examples, structure 116 may be a deep trench isolation, that is, a trench filled with an insulator, the deep trench isolation preferably being bordered by a passivation layer, for example a heavily-doped layer of a conductivity type opposite to that of the substrate.

Pixel 1 is configured to receive light on the side of surface 102 of substrate 100.

Preferably, although this is not illustrated in the drawing, a spectral filter (for example, a color filter, for example a Bayer grid) is arranged above surface 102. Thus, the light arriving on the side of surface 102 has been previously filtered by the filter. Thus, the light reaching surface 102 only corresponds to one wavelength range or color, for example, green, red, or blue for an RGB sensor. More generally, the filter(s) arranged at the side of the surface 102 are configured so that light arriving at surface 102, after filtering, belongs to only one range of wavelengths. This enables to avoid chromatic aberrations linked to the difference in penetration of photons into the substrate as a function of their wavelength. Indeed, pixel 1 is not provided to receive photons in two distinct wavelength ranges and to deliver a signal representative of the quantity of light received in a first of the two ranges with a first of the two photodiodes PD1 and PD2, and a signal representative of the quantity of light received in the second of the two ranges with the second of the two photodiodes PD1 and PD2. In other words, pixel 1 is not a multispectral pixel.

Further, as previously indicated, the charges photogenerated during a phase of light integration by pixel 1 and which accumulate in the photodiodes PD1 and PD2 of pixel 1 are read, during a readout phase, from surface 104 of pixel 1.

Thus, pixel 1 comprises at least one sense node arranged in the portion of substrate 100 where the photodiodes PD1 and PD2 of pixel 1 are arranged, this or these sense node(s) being arranged on the side of surface 104, for example flush with surface 104. In practice, each sense node corresponds to one or more doped regions of the same type as substrate 100, for example with a higher doping level than the doping level of substrate 100.

Further, to control transfers of photogenerated charges from photodiode PD1 to the sense node and transfers of photogenerated charges from photodiode PD2 to the sense node, pixel 1 comprises at least one vertical transfer gate. This or these vertical transfer gate(s) penetrate vertically into the substrate portion comprising photodiodes PD1 and PD2, from surface 104. As an example, the transfer gate(s) penetrate(s) the substrate across part only of the thickness of substrate 100, for example less deeply than photodiode PD1.

In the embodiment of FIGS. 1 to 4, pixel 1 comprises one sense node per photodiode and, further, one vertical transfer gate per photodiode.

More particularly, pixel 1 comprises a sense node SN1 associated with photodiode PD1, and a transfer gate TG1 associated with photodiode PD1 and configured to control charge transfers from photodiode PD1 to sense node SN1. Further, pixel 1 comprises a sense node SN2 associated with photodiode PD2, and a transfer gate TG2 associated with photodiode PD2 and configured to control charge transfers from photodiode PD2 to sense node SN2.

Nodes SN1 and SN2 are arranged in the respective photodiodes PD1 and PD2, on the side of surface 104. Gates TG1 and TG2 penetrate the respective photodiodes PD1 and PD2.

Each vertical transfer gate TG1, TG2 is a deep capacitive isolation trench, that is, a trench filled with an electrically-conductive core 128 covered by an insulating sheath 130.

Node SN1 is, in the example of FIGS. 1 to 4, arranged between CDTI-type structure 116 and vertical transfer gate TG1. Node SN1 is, for example, in contact with a region of photodiode PD1 doped with the same doping type as node SN1 but with a lower doping level, for example the doping level of substrate 100, which extends between structure 116 and gate TG1 and which is used as a channel region for a vertical transistor having its gate corresponding to gate TG1. Similarly, SN2 node is, in the example of FIGS. 1 to 4, arranged between CDTI-type structure 116 and vertical transfer gate TG2. Node SN2 is, for example, in contact with a region of photodiode PD2 doped with the same doping type as node SN2 but with a lower doping level, for example the doping level of substrate 100, which extends between structure 116 and gate TG2 and is used as a channel region for a vertical transistor having its gate corresponding to gate TG2. In this example, the portion of structure 116 which is arranged opposite gate TG1, respectively TG2, contributes to the electrostatic control of the channel of the transistor comprising gate TG1, respectively TG2.

However, those skilled in the art will be capable of providing other arrangements of node SN1 and of gate TG1 in photodiode PD1, and other arrangements of node SN2 and of gate TG2 in photodiode PD2, so that a control potential applied to the conductive core 128 of gate TG1 controls charge transfers from photodiode PD1 to node SN1, and a control potential applied to the conductive core 128 of gate TG2 controls charge transfers from photodiode PD2 to node SN2. For example, each transfer gate TG1, TG2 may be implemented by a ring-shaped transfer gate at the center of which is arranged the corresponding node SN1 or SN2, in which case structure 116 does not take part in the electrostatic control of the corresponding transistor channel. As still another example, each transfer gate TG1, TG2 may be implemented by two portions separate from each other, arranged opposite each other and being parallel to each other, the corresponding node SN1 or SN2 then being arranged between these two portions of the transfer gate and structure 116 then not taking part in the electrostatic control of the channel of the corresponding transistor.

During a light integration phase, gates TG1 and TG2 are controlled by their respective control potentials so that the charges photogenerated in photodiode PD1, respectively PD2, are not transferred to node SN1, respectively SN2. As an example, when the quantity of charges photogenerated in photodiode PD1, respectively PD2, becomes greater than the quantity of charges that can be stored in photodiode PD1, respectively PD2, the excess charges can then reach node SN1, respectively SN2, which then is used as an anti-blooming device.

During a readout phase, gates TG1 and TG2 are controlled by their respective control potentials, so that the charges photogenerated in photodiode PD1, respectively PD2, are transferred to node SN1, respectively SN2. These two charge transfers may be simultaneous or performed one after the other, and are independent of each other in that each photodiode PD 1, PD2 comprises its own transfer gate and its own sense node.

In the example of embodiment of FIGS. 1 to 4, each photodiode PD1, PD2 has its own sense node SN1, SN2 and its own transfer gate TG1, TG2.

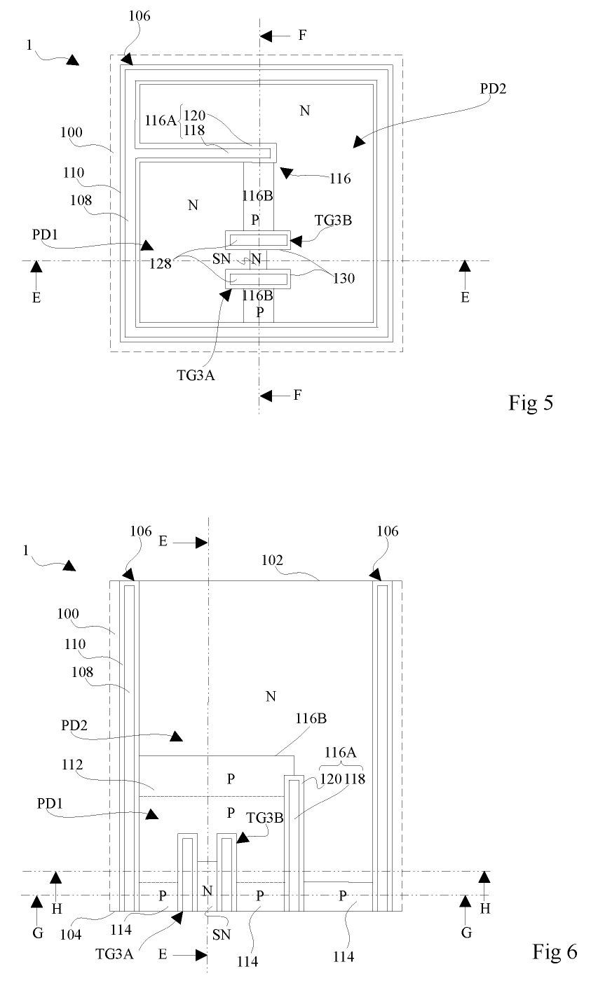

In alternative embodiments, the photodiodes PD1, PD2 of pixel 1 share a same sense node and a same transfer gate, as will now be described in relation with FIGS. 5 to 8.

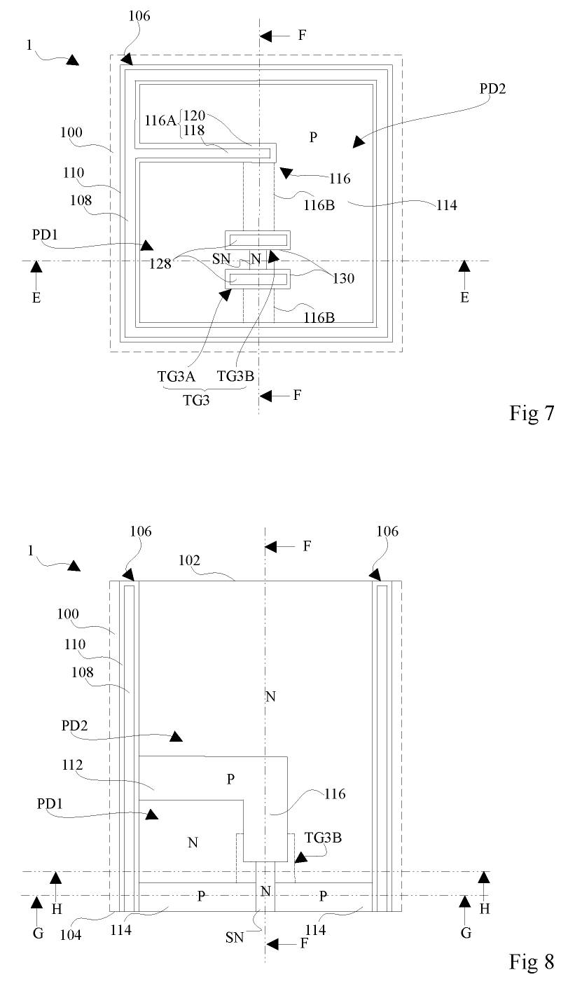

FIGS. 5 to 8 are simplified cross-section views illustrating a variant of HDR pixel 1. More particularly, FIG. 5 is a cross-section view taken in a cross-section plane HH, FIG. 6 is a cross-section view taken in a plane FF orthogonal to plane HH, FIG. 7 is a cross-section view taken in a plane GG, and FIG. 8 is a cross-section view taken in a plane EE orthogonal to plane FF and to planes HH and GG.

The pixel 1 of FIGS. 5 to 8 has many similarities with the pixel 1 of FIGS. 1 to 4, and only the differences between these two pixels are here detailed. Thus, unless otherwise indicated, what has been previously indicated for the pixel 1 of FIGS. 1 to 4 applies to the pixel 1 of FIGS. 5 to 8.

A difference of the pixel 1 of FIGS. 5 to 8 with that of FIGS. 1 to 4 is that the structure 116 of the pixel 1 of FIGS. 5 to 8 is at least partly implemented by a vertical doped wall (or well) of the conductivity type opposite to substrate 100.

More particularly, in the illustrated example, structure 116 comprises a doped vertical wall 116B of the conductivity type opposite to substrate 100 and a capacitive deep isolation capacitor 116B. For example, the portion 116A of structure 116 separates photodiode PD1 from a first part of the photodiode and extends horizontally in the plane of FIG. 5, and the portion 116A of structure 116 separates photodiode PD1 from a second part of photodiode PD2 and extends vertically in the plane of FIG. 5. In FIG. 6, dotted lines mark the boundary between wall 116B and well 114, and between wall 116B and well 112.

As an alternative example not shown, the portion 116A of structure 116 may be replaced with an extension of wall 116B, structure 116 then being entirely implemented by wall 116B.

Another difference independent of the difference highlighted hereabove, but which may be combined with the difference highlighted hereabove, as is the case in the example of FIGS. 5 to 8, is that the pixel 1 of FIGS. 5 to 8 comprises a single sense node SN and a single vertical transfer gate TG.

In the example of FIGS. 5 to 8, transfer gate TG3 comprises two capacitive deep isolation trenches TG3A and TG3B arranged opposite each other and parallel to each other, node SN being arranged between the two portions TG3A and TG3B of gate TG3. In FIG. 8, dotted lines materialize portion TG3B of gate TG3.

In alternative examples, not shown, one or the other of the portions TG3A or TG3B of gate TG3 may be omitted. However, the electrostatic control of charge transfer from photodiodes PD1 and PD2 to node SN will be poorer.

The assembly of gate TG3 and of node SN is arranged in a region of structure 116 where structure 116 is interrupted across only part of its depth, on the side of surface 104. As an example, in the region of structure 116 having the assembly of node SN and of gate TG3 arranged therein, structure 116 is interrupted, from surface 104, down to a depth corresponding to that of node SN.

Thus, node SN is arranged astride the two photodiodes PD1 and PD2, or, in other words, between photodiodes PD1 and PD2. Gate TG3 is also arranged astride (or between) photodiodes PD1 and PD2. More particularly, gate TG3 is arranged so that, when gate TG3 receives a control potential blocking, respectively authorizing, charge transfer from photodiode PD1 to node SN, this blocks, respectively authorizes, the charge transfer from photodiode PD2 to node SN. Both photodiodes PD1 and PD2 are thus read simultaneously.

As an example, in FIGS. 5 to 8, the assembly of node SN and of gate TG3 are arranged in a portion of structure 116 where the latter is interrupted across part of its depth, corresponding to wall 116B. More particularly, as shown in FIG. 7, the two portions TG3A and TG3B of gate TG3 are parallel to each other in a direction from photodiode PD1 to photodiode PD2, that is, a horizontal direction in FIG. 6.

An advantage of having a single transfer gate and a single detection gate for the two photodiodes PD1 and PD2 of pixel 1 is that there is no discontinuity in the signal-to-noise ratio (SNR) over the entire dynamic range of pixel 1.

Another advantage linked to the arrangement of node SN between the two portions TG3A and TG3B is to prevent charges stored in the more sensitive photodiode, for example, PD2, from filling the less sensitive photodiode, for example, PD1, in case of blooming.

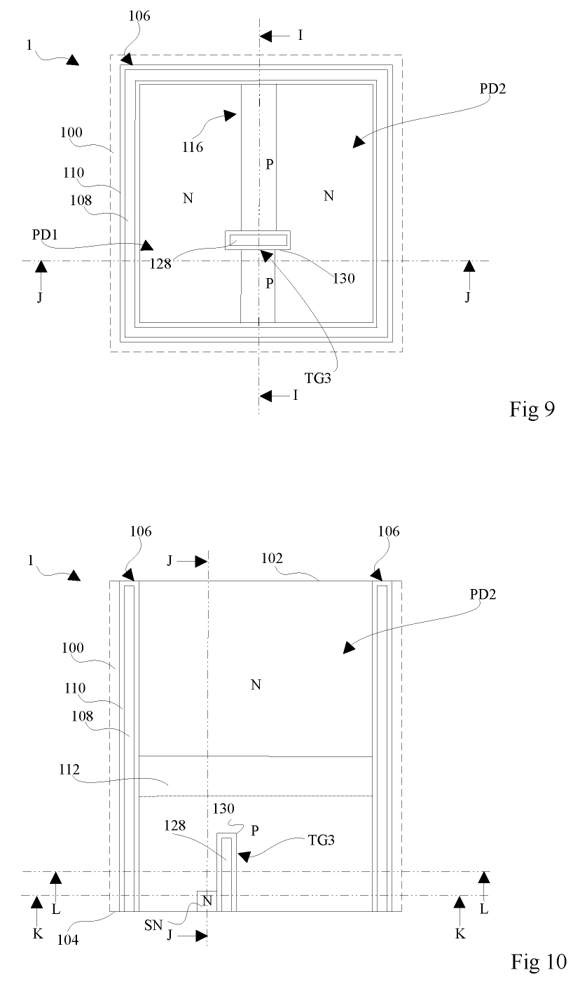

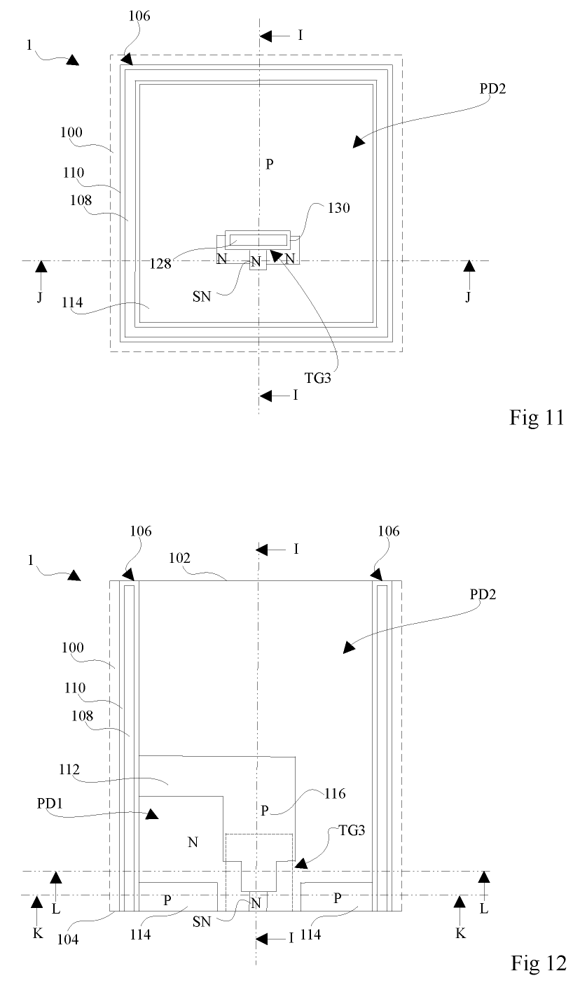

FIGS. 9 to 12 are simplified cross-section views illustrating another variant of HDR pixel 1. More particularly, FIG. 9 is a cross-section view taken in a cross-section plane LL, FIG. 10 is a cross-section view taken in a plane II orthogonal to plane LL, FIG. 11 is a cross- section view taken in a plane KK parallel to plane LL, and FIG. 12 is a cross-section view taken in a plane JJ orthogonal to plane II and to planes KK and LL.

The pixel 1 of FIGS. 9 to 12 has many similarities with the pixel 1 of FIGS. 5 to 8, and only the differences between these two pixels are detailed herein. Thus, unless otherwise indicated, what has been previously indicated for the pixel 1 of FIGS. 5 to 8 applies to the pixel 1 of FIGS. 9 to 12.

A difference between the pixel 1 of FIGS. 9 to 12 and that of FIGS. 5 to 8 is that structure 116 is entirely implemented by a doped wall similar to the wall 116B of FIGS. 5 to 8, and thus does not comprise capacitive deep isolation trench 116A. In FIG. 10, the boundary between wall 116 and well 112 is materialized by dotted lines.

For example, in a plane parallel to surfaces 102 and 104 and running through the two photodiodes PD1 and PD2, wall 116A cuts into two equal parts the portion of substrate 100 which is delimited by structure 106, so that the two photodiodes PD1 and PD2 have the same dimensions in this plane.

Independently of the difference described hereabove, another difference between the pixel 1 of FIGS. 9 to 12 and that of FIGS. 5 to 8 is that transfer gate TG3 comprises only one portion, and not two parallel portions TG3A and TG3B as described in relation with FIGS. 5 to 8. In FIG. 12, dotted lines materialize gate TG3, which is in practice not visible as it is does not form part of the cross-section plane corresponding to this drawing.

As an example, as can be seen in FIGS. 11 and 12, layer 114 may be interrupted around an area of contact of node SN with gate TG3.

As an example, as can be seen in FIGS. 9 and 12, gate TG3 may penetrate doped wall 116, and, further, the portion of the wall 116 arranged below node SN and extending from node SN to the bottom of gate TG3 may be thinner than the rest of wall 116.

As an example, in FIGS. 9 to 12, in planes parallel to surfaces 102 and 104, as illustrated for example in FIGS. 9 and 11, gate TG3 extends lengthwise in a direction orthogonal to the lengthwise extension direction of wall 116. However, as an alternative example, gate TG3 and wall 116 may extend lengthwise in a same direction.

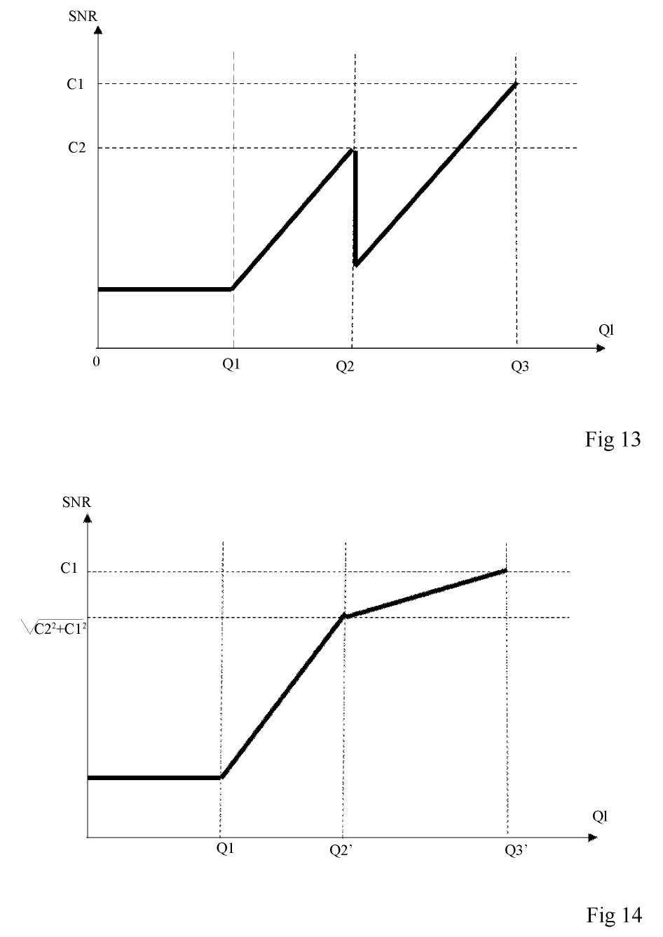

FIG. 13 is a curve illustrating the variation of the signal-to-noise ratio (SNR) of an output signal of pixel 1 as a function of the quantity of light, Ql, received by pixel 1.

This curve is obtained when pixel 1 is configured so that the two photodiodes PD1 and PD2 are read independently of each other, for example when pixel 1 comprises:

a single sense node common to the two photodiodes PD1 and PD2, but two transfer gates respectively enabling to control charge transfers from photodiode PD1 to the single sense node, and charge transfers from photodiode PD2 to the single sense node, or

an assembly of a separate sense node and of a transfer gate for each photodiode PD1 and PD2.

For a quantity of received light smaller than a quantity Q1, the SNR is constant and minimum.

When the quantity of light is between quantity Q1 and a quantity Q2, the SNR increases with the quantity of light received, up to a maximum value determined by C2, with C2 the capacitance value of photodiode PD2, and with a slope determined by the quantum efficiency of photodiode PD2.

When the quantity of light reaches value Q2, photodiode PD2 is full and can no longer store additional charges, or, in other words, photodiode PD2 saturates. The charges read from photodiode PD1 are then used to determine the output signal of the pixel.

However, as can be seen in FIG. 13, this independent reading out of the charges of photodiode PD1 and of the charges of photodiode PD2 leads to a discontinuity in the variation of the SNR when the quantity of received light becomes greater than Q2. Indeed, up to quantity Q2, the SNR increases and only depends on photodiode PD2, after which it abruptly decreases when the quantity of light becomes greater than Q2, before increasing again with the quantity of light and only depending on photodiode PD 1.

When the quantity of light is between quantity Q2 and a quantity Q3, the SNR increases with the quantity of light received, up to a maximum value determined by C1, with C1 the capacitance value of photodiode PD 1, and with a slope determined by the quantum efficiency of photodiode PD1. When the quantity of light reaches value Q3, photodiode PD1 is full and can no longer store additional charges, or, in other words, photodiode PD1 saturates.

FIG. 14 is a curve illustrating the variation of the signal-to-noise ratio (SNR) of an output signal of pixel 1 as a function of the quantity of light, Ql, received by pixel 1.

This curve is obtained when pixel 1 is configured so that the two photodiodes PD1 and PD2 are read simultaneously and all the charges stored in these photodiodes PD1 and PD2 are transferred to the same sense node (referred to as "binning").

For a quantity of received light smaller than a quantity Q1, the SNR is constant and minimum.

When the quantity of light is between quantity Q1 and a quantity Q2', the SNR increases with the quantity of light received, up to a maximum value determined by the square root of sum C12 + C22, with C1 the capacitance value of photodiode PD2 and C2 the capacitance value of photodiode PD2, and with a slope determined by the square root of the sum of the square of the quantum efficiency of photodiode PD2 and of the square of the quantum efficiency of photodiode PD 1.

When the quantity of light reaches value Q2', photodiode PD2 is full and can no longer store additional charges, or, in other words, photodiode PD2 saturates. The variation of the output signal of pixel 1 for received quantities of light greater than Q2' then only depends on the increase in the number of charges in photodiode PD1.

When the quantity of light is between quantity Q2' and a quantity Q3', the SNR increases with the quantity of light received, up to a maximum value determined by C1, with C1 the capacitance value of photodiode PD 1, and with a slope determined by the quantum efficiency of photodiode PD 1.

As compared with the case of FIG. 13, advantageously, in the case of FIG. 14, the SNR exhibits no discontinuity.

Examples of embodiments and of variants have been described in which pixel 1 comprises a photodiode PD1 having a greater storage capacitance is arranged in a photodiode PD2 having a smaller storage capacitance, a portion of photodiode PD2 extending between photodiode PD1 and the surface 102 of the substrate on the side of which pixel 1 receives light, so as to absorb part of this light before it reaches photodiode PD1. Those skilled in the art will be capable of generalizing these examples to the case where the pixel comprises a third photodiode having an even greater storage capacitance than that of photodiode PD1, this third photodiode being arranged in photodiode PD 1 and insulated from the two photodiodes PD 1 and PD2, and part of photodiode PD1 being arranged between the third photodiode and the side 102 of the substrate from which pixel 1 receives light, so as to absorb part of this light before it reaches the third photodiode, and so on.

Further, various examples of the arrangement of one or more sense nodes and of one or more vertical transfer gates have been described. Those skilled in the art will be capable of providing other arrangements of detection node(s) and of transfer gate(s) in the case where:

the photodiodes of the pixel share a common sense node and each photodiode is associated with a separate transfer gate controlling charge transfers from this photodiode to the sense node; or

the photodiodes of the pixel share a same sense node and a same transfer gate controlling simultaneous charge transfers from the photodiodes to the sense node; or

each photodiode of the pixel is associated with its own assembly of a detection node and of a transfer grid so that each photodiode can be read independently of the other photodiodes of the pixel.

Further, those skilled in the art will be capable of adapting the previously-described examples where substrate 100 is N-type doped and the photogenerated charges accumulated in a photodiode during a light integration phase are electrons, to the case where substrate 100 is P-type doped and the photogenerated charges accumulated in a photodiode during a light integration phase are holes, for example by inverting all the conductivity types indicated hereabove as an example.

Various embodiments and variants have been described. Those skilled in the art will understand that certain features of these various embodiments and variants may be combined, and other variants will occur to those skilled in the art. In particular, those skilled in the art will be capable of implementing a light or image sensor comprising one or more pixels such as described hereabove, this sensor then comprising a control circuit configured to apply the control potential(s) to the transfer gate(s) of each pixel.

Finally, the practical implementation of the described embodiments and variants is within the abilities of those skilled in the art based on the functional indications given hereabove. In particular, although this has not been detailed, those skilled in the art will be capable of providing a circuit for biasing structure 106 when it is of CDTI type and a CDTI-type part of structure 116 so that a doped layer of a conductivity type opposite to that of substrate 100 is formed along these structures.

1. A high dynamic range pixel, comprising:
a portion of a semiconductor substrate extending vertically across the entire thickness of the substrate from a first surface to a second surface of the substrate, and being laterally delimited by a vertical insulating structure; and
a first pinned photodiode and a second pinned photodiode arranged in said portion, in which:the first pinned photodiode extends vertically across only part of the thickness of the substrate, on the side of the first surface, and is configured to sense a first range of wavelengths;
and the second pinned photodiode extends vertically across the substrate between the first and second surfaces, comprises a first portion arranged between the first pinned photodiode and the second surface and a second portion arranged between the first pinned photodiode and the vertical insulating structure, and is also configured to sense the first range of wavelengths.

2. The pixel according to claim 1, wherein the pixel is configured to receive light on the side of the second surface.

3. The pixel according to claim 2, wherein the first and second pinned photodiodes are configured so that a photogenerated charge storage capacitance of the first pinned photodiode is greater than that of the second pinned photodiode.

4. The pixel according to claim 3, further comprising a filter extending over the second surface, wherein said filter is configured to pass light only in first range of wavelengths.

5. The pixel according to claim 1, wherein the first pinned photodiode is configured for higher light conditions in the first range of wavelengths and the second pinned photodiode is configured for sensing lower light conditions in the first range of wavelengths.

6. The pixel according to claim 5, wherein a capacitance of the first pinned photodiode for sensing lower light conditions is greater than a capacitance of the second pinned photodiode for sensing higher light conditions.

7. The pixel according to claim 1, wherein the first pinned photodiode is configured to have a first light sensitivity in the first range of wavelengths, wherein the second pinned photodiode is configured to have a second light sensitivity in the first range of wavelengths, and wherein the first light sensitivity is less sensitive than the second light sensitivity.

8. The pixel according to claim 1, wherein the second portion of the second pinned photodiode is arranged between the first pinned photodiode and the vertical insulating structure in planes parallel to the first and second surfaces.

9. The pixel according to claim 1, wherein the first and second pinned photodiodes are insulated from each other.

10. The pixel according of claim 1, wherein the substrate is doped with a first conductivity type, and a doped region of a second conductivity type is arranged between the first pinned photodiode and the first part of the second pinned photodiode so as to insulate the first and second pinned photodiodes from each other.

11. The pixel according to claim 1, wherein the pixel comprises at least one sense node arranged in the portion of the substrate on the side of the first surface, and at least one vertical transfer gate penetrating the portion of the substrate from the first surface and being configured to control charge transfers from the first pinned photodiode to said at least one sense node and from the second pinned photodiode to said at least one sense node.

12. The pixel according to claim 11, wherein said at least one sense node comprises a single sense node.

13. The pixel according to claim 11, wherein:
said at least one sense node comprises a first sense node and a second sense node;
said at least one transfer gate comprises a first transfer gate configured to control charge transfers from the first pinned photodiode to the first sense node, and a second transfer gate configured to control charge transfers from the second pinned photodiode to the second sense node.

14. A light sensor comprising:
at least one pixel according to claim 11; and
a circuit for controlling said at least one transfer gate, wherein the circuit is configured,
during a phase of reading from said at least one pixel, to simultaneously control a charge transfer from the first pinned photodiode to the single sense node and a transfer of photogenerated charges from the second pinned photodiode to the single sense node.
